(19) United States
(12) Patent Application Publication
(10) Pub. No.: US 2009/0050203 A1
(43) Pub. Date: Feb. 26, 2009

(54) DYE-SENSITIZED PHOTOELECTRIC CONVERSION DEVICE

(75) Inventors: Tsutomu Miyasaka, Tokyo (JP); Nobuyuki Ikeda, Yokohama-shi (JP)

Correspondence Address: SUGHRUE MION, PLLC, 2100 PENNSYLVANIA AVENUE, N.W., SUITE 800, WASHINGTON, DC, 20037, US

(73) Assignees: TEIJIN DUPONT FILMS JAPAN LIMITED, Tokyo (JP); TOIN GAKUEN, Yokohama-shi (JP)

(21) Appl. No.: 12/035,613

(22) Filed: Feb. 22, 2008

(30) Foreign Application Priority Data
Aug. 22, 2007 (JP) 2007-216282

(51) Int. Cl. H01L 31/00

(52) U.S. Cl. 136/261

(57) ABSTRACT

There is provided a dye-sensitized photoelectric conversion element comprising a porous photoelectrode layer which comprises dye-sensitized porous semiconductor particles, a charge transport layer and an opposite electrode layer in this order, the charge transport layer comprising a solid mixture comprising 0.1 to 50 wt % of carbon material and 50 to 99.9 wt % of ionic liquid based on the total weight thereof, the charge transport layer comprising at most 1 wt % of iodine and at most 0.9 wt % of p-type conductive polymer or comprising neither iodine nor the p-type conductive polymer.

### BACKGROUND OF THE INVENTION

(i) Field of the Invention This invention relates to a solid dye-sensitized photoelectric conversion element.

(ii) Description of the Related Art

In recent years, as photoelectric conversion elements which convert solar energy into electric power, solid, so-called pn-junction solar cells using a silicon crystal or amorphous silicon thin film or a non-silicon compound semiconductor multilayer thin film have been studied intensively. However, these solar cells have problems of high plant costs and long energy payback time because they are produced at high temperatures or under vacuum. As next-generation solar cells that will replace these conventional solar cells, development of organic solar cells that can be produced at low temperatures and lower costs has been expected. Inter alia, special attention has been paid to dye-sensitized solar cells that can be mass-produced in the atmosphere at low costs, and a high-efficiency photoelectric conversion method using a dye-sensitized porous semiconductor film has been proposed (See, “Nature”, Vol. 353, 1991, pp. 737 to 740, U.S. Pat. No. 4,927,721, Japanese Patent Application Laid-Open No. 100416/2002 and WO00/72373 A1).

The dye-sensitized solar cells use solid (semiconductor)-liquid (electrolyte) junction, so-called wet solar cells, in place of solid (semiconductor)-solid (semiconductor) junction in the conventional solar cells and are a promising source of electrical energy in that the energy conversion efficiency thereof is a high value of 11%.

Many of the dye-sensitized solar cells are produced by use of glass substrates. Further, studies on development of flexible solar cells which have excellent portability and safety and lead to a production cost reduction by a printing method by use of lightweight plastic substrates or films in place of glass have also been intensified.

However, the dye-sensitized solar cells generally use a fluid, liquid electrolyte as a charge transport layer. Thus, when the solar cells are made flexible, such structural degradations as leakage of the electrolyte, elution of dye into the liquid and detachment of semiconductor film occur, and the solar cells have lower storage durability than solid junction type elements.

To solve this problem, such a method using a polymer gel electrolyte as disclosed in Japanese Patent Application Laid-Open Nos. 142168/2003 and 319197/2004 and such a method of transforming the liquid electrolyte of the dye-sensitized solar cell into a quasi-solid state by use of a highly viscous electrolyte containing various nanoparticles such as carbon nanotube as disclosed in Japanese Patent Application Laid-Open No. 93075/2005 have been proposed. However, even with these methods, complete solidification of the charge transport layer cannot be achieved, although flowability of the electrolyte can be controlled. Meanwhile, K. Tennakone et al., Journal of Physics D: Applied Physics, Vol. 31, pp. 1492 to 1496, 1998 discloses a method using solid particles such as copper iodide that is a p-type semiconductor in place of electrolyte liquid, and Chemical Communications, pp. 1886 to 1888 (2005) discloses a method of producing a wholly solid dye-sensitized solar cell by using polyvinyl carbazole as a conductive polymer as a solid charge transport layer that replaces the electrolyte layer. However, these solidification methods have a problem that a fill factor decreases and energy conversion efficiency lowers due to high internal resistance of the solid charge transport layer.

### SUMMARY OF THE INVENTION

The present invention has been conceived under such circumstances to provide a high-efficiency wholly solid photoelectric conversion element based on a dye sensitization technique.

The present inventors have found that a mixture of a carbon material and ionic liquid is effective for forming a solid charge transport layer that changes into an electrolyte and for improving energy conversion efficiency of solid dye-sensitized solar cell significantly and completed the present invention based on this finding.

That is, the present invention provides a dye-sensitized photoelectric conversion element comprising a photoelectrode layer that comprises a dye-sensitized porous semiconductor particle layer, a charge transport layer and an opposite electrode layer in this order, the charge transport layer comprising a solid mixture comprising 0.1 to 50 wt % of carbon material and 50 to 99.9 wt % of ionic liquid based on the total weight of the carbon material and the ionic liquid, the charge transport layer comprising at most 1 wt % of iodine and at most 0.9 wt % of p-type conductive polymer or comprising neither iodine nor the p-type conductive polymer.

According to the present invention, there is obtained a solid dye-sensitized solar cell that does not use a volatile liquid electrolyte and has excellent durability, a long life and high energy conversion efficiency, particularly a large-area, solid dye-sensitized photocell having a flexible structure, as a photoelectric conversion element.

### BRIEF DESCRIPTION OF THE DRAWINGS

FIG. 1 is a cross-sectional diagram illustrating an exemplary constitution of photoelectric conversion element according to the present invention.

### DETAILED DESCRIPTION OF THE PREFERRED EMBODIMENTS

A photoelectric conversion element of the present invention is a solid dye-sensitized photoelectric conversion element having a sandwich structure prepared by having a flexible solid conductive material layer of a mixture composed essentially of a carbon material and ionic liquid contact a photoelectrode that is a dye-sensitized semiconductor thin-film layer obtained by adsorbing dye to a porous semiconductor fine particle layer and having an opposite electrode substrate contact the flexible solid conductive material layer.

Next, the present invention will be further described with reference to the attached drawings.

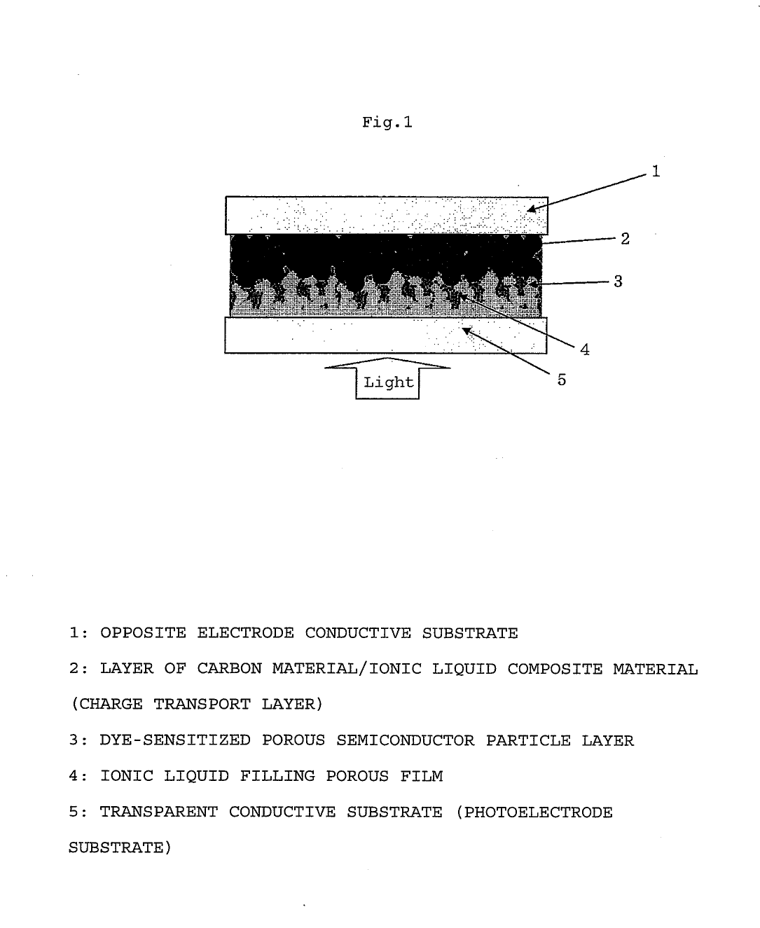

FIG. 1 is a cross-sectional diagram illustrating an exemplary constitution of photoelectric conversion element according to the present invention. The cell is a flat photoelectric conversion element constituted by a laminated structure comprising an opposite electrode conductive substrate 1, a layer 2 of carbon material/ionic liquid composite material, a dye-sensitized porous semiconductor particle layer (photoelectrode layer) 3, ionic liquid 4 that fills the porous film, and a transparent conductive substrate (photoelectrode substrate) 5.

In the present invention, as the transparent conductive substrate which supports the porous semiconductor particle layer, various substrates that can support a transparent conductive layer such as glass or resins can be used. A flexible substrate is preferably used, and a plastic film substrate that supports a transparent conductive layer is particularly preferably used. As the plastic material, a material which is uncolored and highly transparent, has high heat resistance and excellent chemical resistance and gas barrier properties and is inexpensive is preferably selected. From this viewpoint, preferable examples of the plastic material include syndiotactic polystyrene (SPS), polyphenylene sulfide (PPS), polycarbonate (PC), polyarylate (PAr), polysulfone (PSF), polyester sulfone (PES), polyether imide (PEI) and transparent polyimide (PI), and copolymers comprising any of these compounds as main components, in addition to polyesters such as polyethylene terephthalate (PET) and polyethylene naphthalate (PEN). Of these, polyesters are preferred in view of chemical stability and costs, polyethylene terephthalate (PET) or polyethylene naphthalate (PEN) is particularly preferred, and polyethylene naphthalate (PEN) is most preferred. These plastic materials may be used alone or in combination of two or more. Illustrative examples of a method of combining two or more of the plastic materials include blending and lamination.

As the transparent conductive layer, metal such as platinum, gold, silver, copper, aluminum or indium, carbon or a conductive metal oxide such as indium-tin composite oxide, tin oxide or zinc oxide is used. Of these, the conductive metal oxide is preferred, and indium-tin composite oxide (ITO), zinc oxide or indium-zinc oxide (IZO) is particularly preferred, because they have high optical transparency. Most preferable is indium-zinc oxide (IZO) having excellent heat resistance and chemical stability.

The conductive layer supported by the transparent conductive plastic film support preferably has a surface resistance of not higher than 20Ω/□, more preferably not higher than 10Ω/□, much more preferably not higher than 5Ω/□. This conductive layer can be provided with an auxiliary lead for current collecting purpose by patterning or the like. Such an auxiliary lead is preferably formed of a low-resistance metallic material such as copper, silver, aluminum, platinum, gold, titanium or nickel. The resistance value of the surface including the auxiliary lead of the transparent conductive layer having the auxiliary lead patterned thereon is preferably not higher than 1Ω/□. A pattern of such an auxiliary lead can be formed on a transparent substrate by an appropriate method such as deposition or sputtering, and the transparent conductive layer made of tin oxide, an ITO film, an IZO film or the like is preferably formed on the pattern.

The photoelectrode layer in the present invention comprises a porous semiconductor particle layer. The porous semiconductor particle layer comprises a so-called mesoporous semiconductor film having nanosized pores formed in a reticulate form therein. As a semiconductor material that forms the porous semiconductor particle layer, a metal oxide and a metal chalcogenide can be used.

Illustrative examples of metal elements in these oxides and chalcogenides include titanium, tin, zinc, iron, tungsten, zirconium, strontium, indium, cerium, vanadium, niobium, tantalum, cadmium, zinc, lead, antimony, bismuth, cadmium, and lead.

Illustrative examples of preferred semiconductor materials include n-type inorganic semiconductors such as TiO₂, TiSrO₃, ZnO, Nb₂O₃, SnO₂, WO₃, Si, CdS, CdSe, V₂O₅, ZnS, ZnSe, SnSe, KTaO₃, FeS₂, and PbS. Of these, more preferred semiconductor materials are TiO₂, ZnO, SnO₂, WO₃ and Nb₂O₃, particularly preferred semiconductor materials are TiO₂, ZnO and SnO₂, and at least one semiconductor selected from composites of the above compounds, and a most preferred semiconductor material is TiO₂.

As for the particle diameters of these semiconductor particles, the average particle diameter of primary particles is preferably 2 to 50 nm, more preferably 2 to 30 nm.

In the dye-sensitized photoelectric conversion element of the present invention, the porous semiconductor particle layer constituted by the above semiconductor particles has dye molecules on the surface of the porous film as admolecules and is sensitized by dye. In the present invention, the thus dye-sensitized porous semiconductor particle layer is substantially formed from only the semiconductor, inorganic oxide and dye, and the porous layer does not contain solids other than the above components as components that constitute the porous layer or components mixed in the porous layer.

A preferable form of the porous semiconductor particle layer in the present invention is such that the proportion of the weight of solids excluding the semiconductor, inorganic oxide and dye to the total weight of the particle layer is less than 2 wt % and porosity represented by a volume fraction that is a percentage of pores in the particle layer is 50 to 85%. This porosity is particularly preferably 65 to 85%. Further, the proportion of the weight of solids excluding the semiconductor, inorganic oxide and dye to the total weight of the porous semiconductor particle layer is particularly preferably less than 1 wt %.

The porous semiconductor particle layer may contain fine particles of two or more types that differ in particle size distribution. In this case, the average size of smaller particles is preferably not larger than 20 nm. To these superfine particles, large particles having an average particle diameter of larger than 200 nm are preferably added in a proportion of 5 to 30% as a weight percentage, for the purpose of improving light absorption.

In the present invention, when a transparent conductive plastic electrode having a photoelectrode comprising a dye-sensitized porous semiconductor particle layer on a transparent conductive plastic film support is used as the photoelectrode, the photoelectrode is produced by a low-temperature film formation technique of forming the semiconductor particle layer on the plastic film support under a low-temperature condition within the range of the heat resistance of the plastic, e.g. at 200° C. or lower, preferably 150° C. or lower. Such low-temperature film formation can be carried out by, for example, pressing, aqueous pyrolysis, electrophoretic deposition or a binder-free coating method of preparing the photoelectrode by coating a particle dispersion free of a binder material such as a polymer.

Of these methods, a film formation method that is particularly preferred in view of ease of production process is the binder-free coating method. The binder-free coating method is characterized in that semiconductor particle dispersed paste used as a coating agent substantially hardly contains an inorganic or organic binder added for binding of semiconductor material. The phrase “substantially hardly contains a binder” indicates that in the composition of the paste, the proportion of the weight of solids excluding the semiconductor and including the binder material to the total weight of the photoelectrode layer is not higher than 2 wt %, preferably not higher than 1 wt %.

In the binder-free coating method, after the semiconductor particle dispersed paste is coated on a plastic substrate or the like, it is heated at 150 to 200° C. to form the photoelectrode layer comprising the porous semiconductor particle layer.

The thus formed photoelectrode layer contains at most 2 wt %, preferably at most 1 wt % of organic binder in particular or contains no organic binder.

As the dye molecules used for sensitization of the porous semiconductor particle layer, various organic or metal-complex-based sensitizing materials that have heretofore been used for spectral sensitization of semiconductor electrode using dye molecules in the field of electrochemistry are used. Illustrative examples of the sensitizing materials include organic dyes such as cyanine, merocyanine, oxonol, xanthene, squalelium, polymethine, coumarin, riboflavin and perylene dyes, and complex-based dyes such as an Ru complex, metallophthalocyanine derivative, metalloporphyrin derivative and chlorophyll derivative. In addition, synthetic dyes and natural dyes described in “Functional Materials”, June issue in 2003, pp. 5 to 18, and organic dyes typified by coumarin described in “Journal of Chemical Physics (J. Chem. Phys.)”, B. Vol. 107, p. 597 (2003) may also be used.

The charge transport layer that is a characteristic constituent of the dye-sensitized photoelectric conversion element of the present invention, substantially comprises a mixture of a carbon material and ionic liquid and is solid and flexible physically contacts the dye-sensitized porous semiconductor particle layer and is laminated on the porous semiconductor particle layer. The flexible solid charge transport layer used in this case is a high-viscosity conductive solid material that can be deformed and processed freely at room temperature. Further, it is a high-viscosity composite material having a shear property and has a very high viscosity of not lower than 100,000 mPs. As for conductivity, the charge transport layer has both electronic conductivity of the carbon material and ionic conductivity of the ionic liquid.

As the carbon material used in the charge transport layer in the present invention, carbon materials having various shapes such as particulate, fibrous, tubular and molecular shapes and various physical properties and excellent electronic conductivity can be used. More specifically, particulate or scale-like carbon materials such as graphite, carbon black and activated carbon, fibrous carbon materials such as nanotube and fibers, and molecular carbon materials such as fullerene can be used. As the particulate carbon materials, a mesoporous carbon material having nanosized pores (pore diameter: 2 to 50 nm), a microporous carbon material (pore diameter: 2 nm or smaller) and a macroporous carbon material (pore diameter: 50 nm or larger) are preferably used. Particularly preferable in the present invention are highly conductive carbon materials. From this purpose, carbon black, graphite and carbon nanotube are preferred, and carbon nanotube is particularly preferred. Illustrative examples of the carbon black include carbon materials such as channel black, furnace black, acetylene black, thermal black, ketjen black, graphite and carbon black, and ISAF, HAF, FEF and SRF carbons. Illustrative examples of the carbon nanotube include single-wall nanotube, double-wall nanotube, multi-wall nanotube, and cup-stud nanotube. The above carbon materials may be used alone or as a mixture or composite of two or more.

The ionic liquid used in the charge transport layer in the present invention is preferably a room-temperature molten salt that melts into liquid around room temperature. Such a room-temperature molten salt is typified by an alkyl imidazolium salt, and illustrative examples thereof include dimethyl imidazolium, methylpropyl imidazolium, methylbutyl imidazolium, methylhexyl imidazolium and salts thereof, and known electrolytes such as a pyridinium salt, imidazolium salt and triazolium salt described in WO95/18456, Japanese Patent Application Laid-Open No. 259543/1996 and Electrochemistry, Vol. 65, No. 11, p. 923 (1997). As the room-temperature molten salt, one that has low viscosity and gives high performance when used in a dye-sensitized photocell is preferred. Preferred examples thereof are disclosed in Japanese Patent Application Laid-Open Nos. 190323/2002, 199961/2001 and 196105/2001, and Functional Materials, 2004, November issue, pp. 7 to 68. The ionic liquid used in the present invention is particularly preferably an iodide salt, most preferably an iodide of an imidazolium derivative.

The ionic liquid in the present invention may be used in a partially gelled or solidified form by adding a polymer such as polyacrylonitrile or polyvinylidene fluoride or an oil gelator to the ionic liquid or by carrying out a crosslinking reaction of a polymer in the ionic liquid. As a method of gelling the ionic liquid by addition of the oil gelator, a method using a compound having an amide structure in a molecular structure is preferred. An example of gelation of electrolyte (Japanese Patent Application Laid-Open No. 185863/1999) and an example of gelation of molten salt electrolyte (Japanese Patent Application Laid-Open No. 58140/2000) are known. Any method can be selected from these known methods and used in the present invention.

The charge transport layer in the present invention preferably uses no iodine (I₂) or at most 1 wt % of iodine based on the charge transport layer. When the iodine content of the charge transport layer exceeds 1 wt %, short-circuit photocurrent density decreases sharply. The content of iodine (I₂) in the charge transport layer is particularly preferably 0 to 0.1 wt %.

The charge transport layer in the present invention preferably contains no p-type conductive polymer or at most 0.9 wt % of p-type conductive polymer based on the total weight of the charge transport layer. When the content of the p-type conductive polymer is higher than 0.9 wt %, an increase in the resistance of charge transport passing through the polymer layer causes a decrease in photocurrent and degradation of photoelectric conversion efficiency, and especially in a photoelectric conversion element using a plastic support and a porous semiconductor particle layer formed at low temperatures, the viscosity of the layer containing the p-type conductive polymer becomes too high, so that the charge transport layer partially damages the porous semiconductor particle layer having a weak interparticle bond disadvantageously. Illustrative examples of the p-type conductive polymer include a polyaniline doped with a sulfonic acid derivative or sulfonate, and polypyrroles doped with various anions.

The charge transport layer in the present invention contains 0.1 to 50 wt %, preferably 1 to 30 wt % of the carbon material and 50 to 99.9 wt %, preferably 70 to 99 wt % of the ionic liquid, based on the total weight of the carbon material and the ionic liquid.

In the present invention, voids in the porous structure of the photoelectrode layer (porous semiconductor particle layer) that contacts the above charge transport layer are preferably filled with ionic liquid. In this case, the ionic liquid filling the voids is particularly preferably an iodide of an imidazolium derivative.

The charge transport layer and ionic liquid that constitute the dye-sensitized photoelectric conversion element of the present invention can contain an organic solvent. Illustrative examples of such an organic solvent include carbonate compounds such as ethylene carbonate and propylene carbonate;

ethylene glycol monoalkyl ether, propylene glycol monoalkyl ether, and polyethylene glycol monoalkyl ether; monoalcohol such as polypropylene glycol monoalkyl eter; polyhydric alcohols such as ethylene glycol, propylene glycol, polyethylene glycol, polypropylene glycol, and glycerin;
ethers such as dioxane, ethylene glycol dialkyl ether, propylene glycol dialkyl ether, polyethylene glycol dialkyl ether, and polypropylene glycol dialkyl ether; lactones such as γ-butyrolactone,
α-methyl-γ-butyrolactone, β-methyl-γ-butyrolactone, γ-valerolactone, and 3-methyl-β-valerolactone; nitrile compounds such as methoxy acetonitrile, propionitrile, benzonitrile, and 3-methoxy propionitrile; and
aprotic polar materials such as dimethyl sulfoxide and sulfolane. Of these, organic solvents having a high boiling point of not lower than 200° C. can be preferably used, and a specific example thereof is propylene carbonate.

In the present invention, as the opposite electrode substrate that physically contacts the charge transport layer, a solid substrate having various metallic materials, oxide conductive materials, conductive polymers or the like as an opposite electrode layer can be used. Illustrative examples of the metallic materials that constitute the opposite electrode layer include metals such as platinum, gold, silver, copper, aluminum, magnesium and indium. Illustrative examples of the oxide conductive materials that constitute the opposite electrode layer include indium-tin composite oxide (ITO), fluorine doped tin oxide (FTO), zinc oxide, and indium-zinc composite oxide (IZO). The most preferable as the oxide conductive material is indium-zinc composite oxide (IZO).

The opposite electrode substrate is preferably a conductive substrate having an opposite electrode layer made of a conductive material other than platinum. Further, the photoelectric conversion element of the present invention is characterized in that it gives high performance without using expensive platinum as a constituent material of the opposite electrode substrate.

As a support for the opposite electrode substrate, a flexible substrate is preferably used as in the case of the support for the photoelectrode. As the flexible substrate, metallic foil, a plastic substrate or the like can be used, for example. As the plastic substrate, polyethylene terephthalate (PET), polyethylene naphthalate (PEN), syndiotactic polystyrene (SPS), polyphenylene sulfide (PPS), polycarbonate (PC), polyarylate (PAr), polysulfone (PSF), polyester sulfone (PES), polyether imide (PEI) and transparent polyimide (PI) and a copolymer comprising any of these compounds as main components are used, for example. Of these, polyethylene terephthalate (PET) and polyethylene naphthalate (PEN) are particularly preferred in view of chemical stability and costs, and polyethylene naphthalate (PEN) is most preferred. These plastic materials may be used alone or in combination of two or more. Illustrative examples of a method of combining two or more of the plastic materials include blending and lamination.

### EXAMPLES

### Example 1

### (1) Production of Dye-Sensitized Photoelectrode Comprising Semiconductor Porous Titanium Dioxide Particle Film

As a transparent conductive plastic film, polyethylene naphthalate (PEN) supporting ITO as a transparent conductive film and having a film thickness of 200 μm and a surface resistance of 13Ω/□ was used. 30 g of rutile-anatase mixed type crystalline titanium dioxide nanoparticles (average particle diameter: 60 nm) and 0.2 g of polyethylene glycol having a molecular weight of 2,000,000 were dispersed into 100 ml of t-butyl alcohol. To this dispersion, 100 ml of acidic sol having titanium dioxide particles having an average particle diameter of 15 nm dispersed in water (titanium dioxide concentration: 8 wt %) was added, and the obtained mixed dispersion was mixed uniformly by means of a rotation/revolution mixing conditioner to prepare viscous titanium dioxide paste. The content of titanium oxide in solids in the paste was 99.4 wt %. This titanium dioxide paste was coated on the ITO side of the ITO-PEN film by a doctor blade method, dried at room temperature and then heated at 150° C. for 5 minutes to obtain an ITO-PEN film supporting a porous titanium dioxide semiconductor film.

The above porous semiconductor film electrode substrate was immersed in a dye solution prepared by dissolving an Ru complex dye having optical absorption at a wavelength of 400 to 800 nm in a mixed solvent of acetonitrile/t-butanol (1:1) at a concentration of 3×10⁻⁴ mol/l, and the solution was agitated at 40° C. for 60 minutes to adsorb the dye to the substrate, thereby producing a dye-sensitized ITO-PEN film electrode.

### (2) Formation of Solid Charge Transport Layer

4 g of ethylmethyl imidazolium iodide as ionic liquid and 0.3 g of single-wall carbon nanotube (Carbon Nanotechnologies Inc.) as a carbon material were mixed together and kneaded in an agate mortar to prepare a solid (clay-like) charge transport layer material.

80 mg of the above charge transport layer material was adhered to 1 cm² of the surface of the porous titanium oxide film of the dye-sensitized ITO-PEN film electrode produced in the above (1) and pressed in the thickness direction of the porous titanium dioxide film by use of a pressing machine. By this operation, a charge transport layer having a thickness of about 50 μm was directly laminated on the porous titanium dioxide film.

### (3) Production of Opposite Electrode Substrate

Polyethylene naphthalate (PEN) supporting ITO as a conductive layer (opposite electrode layer) and having a film thickness of 200 μm and a surface resistance of 13Ω/□ was used.

### (4) Preparation of Solid Dye-Sensitized Photoelectric Conversion Element

The ITO conductive layer side of the opposite electrode substrate obtained in the above (3) was placed on the surface of the solid charge transport layer formed on the porous titanium dioxide film in the above (2) and pressure-bonded by means of a pressing machine to produce a sandwich-type, flexible, film-shaped, solid dye-sensitized photoelectric conversion element having a thickness of about 500 μm and an effective light-receiving area of 1 cm².

### (5) Evaluation of Photoelectric Conversion Characteristics of Solid Dye-Sensitized Photoelectric Conversion Element

By use of a pseudo sunlight source (simulator) having a 500-W xenon lamp, AM 1.5 pseudo sunlight having an incident light intensity of 100 mW/cm² was applied, from the dye-sensitized ITO-PEN film electrode side, to the solid dye-sensitized photoelectric conversion element obtained in the above (4). The photoelectric element was closely attached and fixed on a stage of a constant-temperature device, and the temperature of the element being irradiated was controlled to 30° C. By use of a current voltage measurement apparatus (SourceMeter 2400 of Keithley Instruments Inc.), a DC voltage applied to the element was scanned at a constant rate of 10 mV/sec, and photocurrent density output from the element was measured to measure photocurrent-voltage characteristics. The thus determined photocurrent densities (J_{sc}), open circuit electromotive forces (V_{oc}), fill factors (FF) and energy conversion efficiencies (η) of the above various elements are shown in Table 1 together with constituents of the cells.

### Examples 2 and 3

Solid dye-sensitized photoelectric conversion elements were produced and photoelectric conversion characteristics were evaluated in the same manner as in Example 1 except that the single-wall carbon nanotube (shown as “SWCNT” in Table 1) was changed to multi-wall carbon nanotube (shown as “MWCNT” in Table 1) or carbon black (shown as “CB” in Table 1). The results are shown in Table 1.

### Examples 4, 5 and 6 and Comparative Examples 1 and 2

Solid dye-sensitized photoelectric conversion elements were produced and photoelectric conversion characteristics were evaluated in the same manner as in Example 1 except that iodine (I₂) was added in amounts shown in Table 2. The results are shown in Table 2.

TABLE 1

| | Carbon | J_{sc} | V_{oc} | | η |
|---|---|---|---|---|---|
| | Material | (mA/cm²) | (V) | FF | (%) |
| Ex.1 | SWCNT | 6.8 | 0.66 | 0.36 | 1.63 |
| Ex.2 | MWCNT | 4.3 | 0.60 | 0.39 | 1.01 |
| Ex.3 | CB | 4.4 | 0.60 | 0.42 | 1.11 |

Ex.: Example

TABLE 2

| | Amount of | | | | |
|---|---|---|---|---|---|
| | I₂ Added | J_{sc} | V_{oc} | | η |
| | (wt %) | (mA/cm²) | (V) | FF | (%) |
| Ex.4 | 0.01 | 6.7 | 0.67 | 0.36 | 1.62 |
| Ex.5 | 0.5 | 6.0 | 0.66 | 0.38 | 1.50 |
| Ex.6 | 1.0 | 5.0 | 0.66 | 0.40 | 1.32 |
| C.Ex.l | 2.0 | 3.5 | 0.64 | 0.40 | 0.90 |
| C.Ex.2 | 2.4 | 2.4 | 0.63 | 0.42 | 0.64 |

Ex.: Example,
C.Ex.: Comparative Example

It has been revealed from the results shown in Tables 1 and 2 that photocurrent density is improved by keeping the amount of iodine (I₂) at 1 wt % or lower. Further, this photoelectric conversion element is a dye-sensitized solar cell having excellent durability because it does not use iodine.

1. A dye-sensitized photoelectric conversion element comprising a photoelectrode layer that comprises a dye-sensitized porous semiconductor particle layer, a charge transport layer and an opposite electrode layer in this order,
the charge transport layer comprising a solid mixture comprising 0.1 to 50 wt % of carbon material and 50 to 99.9 wt % of ionic liquid based on the total weight thereof,
the charge transport layer comprising at most 1 wt % of iodine and at most 0.9 wt % of p-type conductive polymer or comprising neither iodine nor the p-type conductive polymer.

2. The dye-sensitized photoelectric conversion element of claim 1, further comprising a plastic film that is a support for the photoelectrode layer, the plastic film having a transparent conductive layer formed thereon.

3. The dye-sensitized photoelectric conversion element of claim 2, wherein the plastic film as a support for the photoelectrode layer is a polyester film.

4. The dye-sensitized photoelectric conversion element of any one of claims 1 to 3, wherein the carbon material constituting the charge transport layer is carbon nanotube.

5. The dye-sensitized photoelectric conversion element of any one of claims 1 to 3, wherein the porous photoelectrode layer comprises at most 2 wt % of organic binder.

6. The dye-sensitized photoelectric conversion element of any one of claims 1 to 3, wherein voids in the porous photoelectrode layer are filled with ionic liquid.
